(19) United States
(12) Patent Application Publication
(10) Pub. No.: US 2023/0039342 A1
(43) Pub. Date: Feb. 9, 2023

(54) HETEROEPITAXIAL GROWTH METHOD OF COMPOUND SEMICONDUCTOR MATERIALS ON MULTI-ORIENTED SEMICONDUCTOR SUBSTRATES AND DEVICES

(71) Applicant: KING ABDULLAH UNIVERSITY OF SCIENCE AND TECHNOLOGY, Thuwal (SA)

(72) Inventors: Nasir ALFARAJ, Thuwal (SA); Kuang-Hui LI, Thuwal (SA); Laurentiu BRAIC, Thuwal (SA); Adrian Emil KISS, Magurele (RO); Nicolae Catalin ZOITA, Magurele (RO)

(21) Appl. No.: 17/792,050

(22) PCT Filed: Jan. 11, 2021
(86) PCT No.: PCT/IB2021/050172

§ 371 Date: Jul. 11, 2022

Related U.S. Application Data
(60) Provisional application No. 62/960,314, filed on Jan. 13, 2020.

(51) Int. Cl. H01L 21/02; H01L 31/032; H01L 29/778

(52) U.S. Cl. CPC H01L 21/02491; H01L 31/032; H01L 29/7786; H01L 21/02381; H01L 21/02565; H01L 21/02631

(57) ABSTRACT

A method for growing a semiconductor material over a Si-based substrate includes providing the Si-based substrate; growing a monocrystalline refractory-metal ceramic film directly over the Si-based substrate; and depositing a semiconductor film directly over the monocrystalline refractory-metal ceramic film. The monocrystalline refractory-metal ceramic film has a thickness less than 300 nm.

### CROSS-REFERENCE TO RELATED APPLICATIONS

This application claims priority to U.S. Provisional Patent Application No. 62/960,314, filed on Jan. 13, 2020, entitled “HETEROEXPITAXIAL GROWTH OF COMPOUND SEMICONDUCTOR MATERIALS ON A COMMON SEMICONDUCTOR SUBSTRATE,” the disclosure of which is incorporated herein by reference in its entirety.

### BACKGROUND

### Technical Field

Embodiments of the subject matter disclosed herein generally relate to optoelectronic devices and methods for making such devices, and more particularly, to a method for heteroepitaxial growth of a compound semiconductor monocrystalline film on a semiconductor monocrystalline silicon (Si) substrate with a thin intermediary layer that minimizes strain.

### Discussion of the Background

In the quest for developing new lighting applications and associated devices, the group III-oxide and group III-nitride alloys are of interest as they are inexpensive to manufacture and have advantageous optical and electronic properties. These materials are currently used for device applications for emitters and detectors in the visible and ultraviolet (UV) portions of the optical spectrum and high-power amplifiers. Group III-oxide and group III-nitride alloys are chemically and thermally robust, exhibit long carrier lifetimes, are operationally stable, and are the only known materials that have wide and direct bandgaps and are wavelength-tunable within the UV regime of operation (from around 200 to 400 nm).

The heterogeneous integration of various forms of inorganic materials into one electronic system is based on group III-oxide and group III-nitride alloys. Examples of systems that need to be integrated on the same substrate, i.e., both electronic devices (e.g., transistors) and optical devices (e.g., optical emitters or receivers), include nanomechanical optical detection devices, solid-state detection devices, piezoelectric resonators and electrical and harmonic generators, strain-gated transistors, single-photon emission devices, various sensors, light switches used in optical networks, white light generation from light-emitting diodes (LEDs) and from laser diodes (LDs), and high-electron-mobility transistors (HEMTs). All of these systems show promise in advancing the development of the “new electronics” industry.

Successful doping and/or alloying of a semiconductive material is required for achieving an efficient carrier injection process to realize excellent device performance characteristics. These characteristics include the tunability of their bandgap energies within a significant portion of the UV spectral range (namely, UV-C below 280 nm, UV-B between 280 and 315 nm, and UV-A between 315 and 400 nm), high chemical and device operational stability and reliability, internal quantum efficiency (IQE), external quantum efficiency (EQE), etc. These properties remain relatively low, and the presence of spontaneous and piezoelectric fields limits their potential.

The main causes of such low efficiency parameters are the high density of threading dislocations (TDs) extending from the surface of a strained layer system, which causes internal structural cracking and the subsequent increase in nonradiative recombination channels within the device active regions. These issues arise mainly from the lattice and thermal mismatches between the grown material and the substrate. Although there are attempts to use a thick buffer layer 110 (e.g., zirconium diboride (ZrB₂), aluminum diboride (AlB₂) or hafnium diboride (HfB₂)), as shown in FIG. 1, between the Si substrate 102 and the deposited semiconductor material 104, for reducing the strain between these layers, the fact that the buffer layer 110 has a thickness T between 1 and 2 μm negatively impacts the electronic and/or optical properties of the semiconductor device 100. For example, an aluminum gallium nitride (AlₓGa₁₋ₓN where 0<x<1)-based heterostructure having the thick buffer layer 110 exhibits poor p-type doping behavior, and generally suffers from significant light extraction losses, particularly toward the deep-ultraviolet (DUV) spectral regime, while conductive n-type AlₓGa₁₋ₓN layers can be realized with relative ease.

Thus, there is a need for a new method and device that not only reduces the strain between the substrate and the semiconductor material that achieves the functionality of the device, but also overcome the problems noted above.

### BRIEF SUMMARY OF THE INVENTION

According to an embodiment, there is a method for growing a semiconductor material over a Si-based substrate. The method includes providing the Si-based substrate, growing a monocrystalline refractory-metal ceramic film directly over the Si-based substrate, and depositing a semiconductor film directly over the monocrystalline refractory-metal ceramic film. The monocrystalline refractory-metal ceramic film has a thickness less than 300 nm.

According to another embodiment, there is a photodetector that includes a Si-based substrate, a monocrystalline refractory-metal ceramic film located directly over the Si-based substrate, a semiconductor film located directly over the monocrystalline refractory-metal ceramic film, and first and second electrodes. The monocrystalline refractory-metal ceramic film has a thickness less than 300 nm.

According to yet another embodiment, there is a transistor that includes a Si-based substrate, a monocrystalline refractory-metal ceramic film located directly over the Si-based substrate, a semiconductor film located directly over the monocrystalline refractory-metal ceramic film, a cap layer formed over the semiconductor film, a dielectric layer formed over the cap layer, a gate formed over the dielectric layer, and a source and drain regions formed directly on the cap layer. The monocrystalline refractory-metal ceramic film has a thickness less than nm.

### BRIEF DESCRIPTION OF THE DRAWINGS

Fora more complete understanding of the present invention, reference is now made to the following descriptions taken in conjunction with the accompanying drawings, in which:

FIG. 1 is a schematic diagram of a traditional device that uses a thick buffer layer between a substrate and a semiconductor layer;

FIG. 2 is a flow chart of a method for making an optoelectronic structure without a thick buffer layer;

FIG. 3 is a schematic diagram of an optoelectronic structure with a thin monocrystalline refractory-metal ceramic film formed between the substrate and the semiconductor film;

FIG. 4 is a schematic diagram of a photodetector including the optoelectronic structure with the thin monocrystalline refractory-metal ceramic film formed between the substrate and the semiconductor film and having two electrodes;

FIG. 5 is a schematic diagram of a transistor including the optoelectronic structure with the thin monocrystalline refractory-metal ceramic film formed between the substrate and the semiconductor film;

FIG. 6 is a schematic diagram of another transistor including the optoelectronic structure with the thin monocrystalline refractory-metal ceramic film formed between the substrate and the semiconductor film;

FIG. 7 is a schematic diagram of a photodetector including the optoelectronic structure with the thin monocrystalline refractory-metal ceramic film formed between the substrate and the semiconductor film;

FIG. 8A is an out-of-plane X-ray diffraction (XRD) pattern of the optoelectronic structure employing a (100)-cut Si substrate and FIG. 8B is an out-of-plane XRD pattern of the optoelectronic structure employing a (111)-cut Si substrate;

FIGS. 9A to 9C are φ-scan skewed asymmetric XRD measurements for the (100)-cut Si substrate, thin monocrystalline refractory-metal ceramic film, and the semiconductor film, respectively, of the resulting crystallographically textured optoelectronic structure, and FIGS. 9D to 9F are φ-scan skewed asymmetric XRD measurements for the (111)-cut Si substrate, thin monocrystalline refractory-metal ceramic film, and the semiconductor film, respectively, of the resulting crystallographically textured optoelectronic structure;

FIG. 10 illustrates β-Ga₂O₃ unit cell configurations for the semiconductor film when employing an optoelectronic structure with a (100)-cut Si substrate;

FIG. 11 illustrates the atomic unit cell configurations in the (100)-cut Si substrate and the monocrystalline refractory-metal ceramic film;

FIG. 12 illustrates the elemental mapping of the optoelectronic structure obtained using energy-dispersive X-ray (EDX) analysis combined with scanning transmission electron microscopy (STEM) and high-angle annular dark-field (HAADF) micrography for an optoelectronic structure employing a (100)-cut Si substrate; and

FIG. 13 illustrates the current-voltage measurements for a DUV photodetector based on the optoelectronic structure illustrated in FIG. 3.

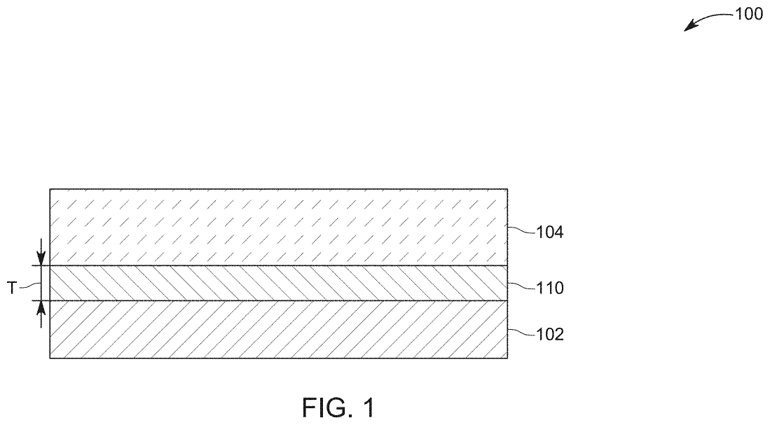

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to an optoelectronic structure that includes a semiconductor layer formed over a semiconductor substrate with a thin monocrystalline refractory-metal ceramic film disposed in between. However, the embodiments to be discussed next are not limited to this optoelectronic structure, but may be applied to other semiconductor structures.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a method for heteroepitaxial growth of a compound semiconductor monocrystalline film on a semiconductor monocrystalline Si substrate with an intermediary film of monocrystalline epitaxial refractory transitional-metal ceramics is presented. The monocrystalline epitaxial refractory transitional-metal ceramics may include one or more of titanium nitride (TiN) [1], titanium carbide (TiC) [2], zirconium nitride (ZrN) [3], yttrium nitride (YN), tantalum nitride (TaN) [4], tantalum carbon (TaC) [5], vanadium nitride (VN) [6], vanadium carbide (VC), niobium carbide (NbC), niobium nitride (NbN), scandium nitride (ScN) [7], hafnium carbide (HfC), chromium nitride (CrN) [8], hafnium nitride (HfN) [9,10], depending on the suitable crystalline lattice match between the intermediary film and the desired semiconductor to be grown. The monocrystalline epitaxial refractory transitional-metal ceramics act as epitaxial growth lattice templates for the compound semiconductor layer. As metallic ceramic templates, the monocrystalline refractory transitional-metal ceramic films act as conductive interlayers that facilitate the heteroepitaxial growth and integration of the compound semiconductor materials, such as group III-oxides and III-nitrides and their associated alloys, on monocrystalline Si substrates. Other similar substrates may be used, for example silicon carbide (SiC), sapphire, etc.

Previously, a semiconductor layer of GaN has been grown on a SiC substrate using epitaxial ScN buffer layers, and on (111)-oriented Si using AlN nucleation layers. The novel method to be discussed next is different from the existing growth technologies in at least the fact that it utilizes high-quality monocrystalline thin films of refractory transitional-metal conductive ceramics, grown on (100)-cut Si or (111)-cut Si wafers, as templates for the growth of the monocrystalline group III-oxides and group III-nitrides and their respective alloys. The use of heteroepitaxial growth of monocrystalline group III-oxides and group III-nitrides and their associated alloys on (100)- and/or (111)-cut Si wafers, without resorting to growing significantly thick buffer layers [11] as the traditional methods do, was not been previously reported.

Si is the least expensive and most commonly used element in semiconductor device fabrication. Given the relative lattice match between the Si and certain refractory transitional-metal ceramics, and between these refractory transitional-metal ceramics and the group III-oxides and group III-nitride and their associated alloys, thin monocrystalline refractory transitional-metal ceramics interlayers having a thickness between 100 nm to 300 nm facilitate the growth of the group III-oxides and group III-nitrides and their respective alloys on the Si platforms (e.g., (100)- and (111)-cut Si), without thick buffer layers. Furthermore, given the interfacial metal-dielectric characteristics exhibited at the interfaces between the refractory transitional-metal ceramics and unintentionally-doped group III-oxide and group III-nitride compound semiconductor alloys, any optoelectronic photodetector that employs this new method is expected to benefit from plasmon-enhanced light-matter interactions, which enable remarkably high optical gains and faster response times to high-frequency signals.

Moreover, this new approach of growing semiconductor materials on Si based substrates makes possible the integration of the optoelectronic devices with conventional electronics because of the abundance and availability of such substrates. Given the high thermal conductivities of the refractory transitional-metal ceramics and Si, electronic devices fabricated based on the proposed method demonstrate remarkable heat dissipation characteristics that will aid in the realization of reliable power electronic devices based on group III-oxide and group III-nitride materials and their respective alloys. As wide bandgap semiconductors, group III-oxides and group III-nitrides and their associated alloys exhibit large breakdown fields (approximately 8 MV cm⁻¹ and 5 MV cm⁻¹, respectively), the issue of poor heat dissipation in power electronic devices that use such semiconductors has not been critically and practically addressed in the field. Hence, the proposed method will provide an excellent platform for high-performance power electronic devices. Furthermore, of these refractory transitional-metal ceramics, polycrystalline TiN has widely been used as a diffusion barrier in microelectronic devices. As the monocrystalline TiN growth require high temperatures, that are not compatible with CMOS technology, it is possible to first grow the TiN film on the Si substrate, and then to grow the other layers, to not expose the CMOS stack to the high temperature required by TiN growth.

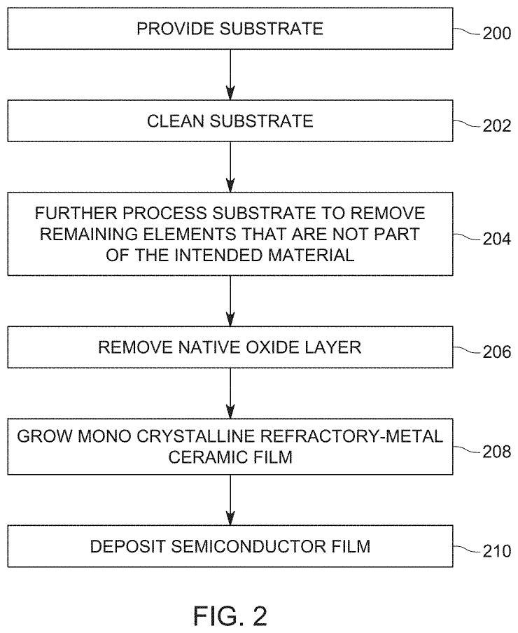

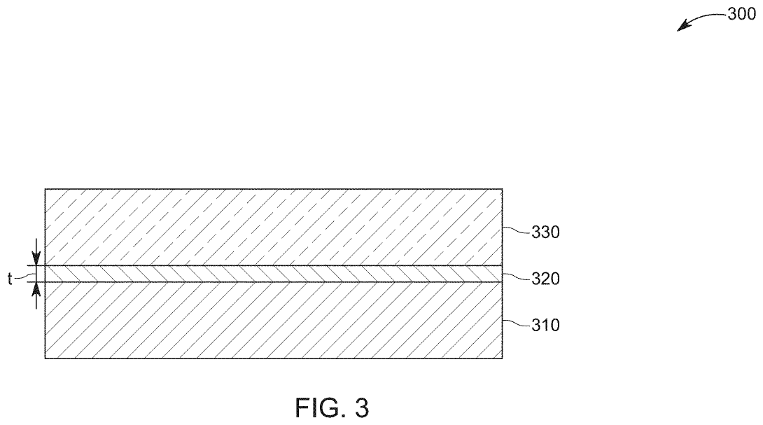

The novel method is now discussed with regard to FIGS. 2 and 3. The method starts in step 200 (see FIG. 2), in which a substrate 310 (see FIG. 3) is provided. In one application, the substrate 310 may be a 10 mm×10 mm (100)-oriented Si substrate and/or an (111)-oriented Si substrate. In step 202, the substrate 310 is cleaned. For example, the substrate may be cleaned in acetone (C₃H₆O) and isopropyl alcohol (IPA, C₃H₆O) in ultrasonic baths. The substrate is then dried in pure nitrogen (N₂) flux immediately before being placed in the sputter deposition vacuum chamber on a metallic substrate holder (80 mm in diameter), which is positioned 170 mm away from the sputtering targets. To remove part of the native oxide layer and other molecules on the Si substrate, such as water vapor and alcohol residue, the substrate 310 can be further processed in optional step 204. For example, the substrate 310 can be biased at 300 V RF and sputter etched in an argon (Ar) ambient at 0.67 Pa for 15 minutes at room temperature, with the whole substrate being placed on the rotating substrate holder. In order to completely eliminate the native oxide layer from the substrate, in optional step 206, the native oxide layer has been evaporated through sublimation in high vacuum. For this step, the Si substrate 310 was kept in high vacuum (8×10⁻⁶ Pa) at 800° C. for 60 minutes. During this cleaning process and a subsequent deposition process, the substrate can be rotated at 50 rpm.

One or more monocrystalline refractory-metal ceramic films 320, e.g., monocrystalline TiN films, were then heteroepitaxially grown in step 208 by radio-frequency (RF) magnetron sputtering method on the cleaned substrate 310, as shown in FIG. 3. The RF magnetron sputtering method can use two metallic titanium (Ti) targets (e.g., 5 mm thick, 50.8 mm diameter, 99.99% purity) in a reactive mixture of Ar and N₂ gases. Both gases were 99.999% pure. A magnetron sputtering system with five unbalanced magnetrons in a confocal geometry was used to deposit the TiN films 320 on the (100)-oriented Si substrate 310. Note that the term “monocrystalline” refers herein to a single crystal. A monocrystalline film implies a uniform film with a certain composition that assumes a single crystal structure throughout. In other words, the term “monocrystalline” implies that no other crystallographic phase or orientation is present; only a single phase (i.e., beta phase Ga₂O₃) is present as pure Ga₂O₃ grown on c-plane sapphire, for example, always exhibits a −201 plane if grown at the right temperature and pressure conditions.

To avoid Ti target gradual poisoning resulting from undesired reactions with N₂ during the reactive deposition (i.e., formation of the compound film on the sputter target in addition to the substrate causing lower yield), the deposition chamber can be evacuated down to 8×10⁻⁶ Pa prior to each deposition process. The Ti target was cleaned by Ar sputtering for five minutes, and then a plasma discharge with the same parameters to be used during film deposition was maintained for five minutes in order to prepare the target surface.

The following deposition conditions were used for step 208: Ar and N₂ mass flow rates were 18.5 sccm and 1.5 sccm, respectively, while the total working gas pressure was kept constant at 0.67 Pa using an automatic pressure control system. Both Ti cathodes were fed in power constant mode, at 180 W, using two RF power supplies and two MC2 Automatic Matching Network Controllers. The substrates were RF biased at 50 V, and the substrate deposition temperature (T_{S}), measured with a backside non-contact thermocouple, was set to about 800° C. The deposition rate, determined by surface profilometry from a step height patterned using a Si mask and the deposition duration, was found to be 1.138 nm per minute. To get the number of needed samples and verify the reproducibility of the deposition process, TiN thin films were deposited on seven samples along with a control one in three different runs with identical deposition process conditions with the same duration of 132 minutes. The deposited TiN film 320 thickness t was approximately 150 nm.

Next, a semiconductor film 330 was grown in step 210 on the monocrystalline refractory-metal ceramic film 320, using pulsed laser deposition (PLD), to obtain an optoelectronic structure 300. The semiconductor film 330 was in this embodiment an unintentionally-doped β-Ga₂O₃ film. The growing step was performed at a T_{S} of 640° C., at an oxygen (O₂) partial pressure of 5 mTorr, a laser pulse frequency of 5 Hz, an energy per pulse of 200 mJ, and a laser fluence of 2 J/cm². The film 330 was deposited in this embodiment with a target-to-substrate distance of 80 mm and 30 k pulses; its thickness was estimated at less than 400 nm, for example, around 320 nm from electron microscopy imaging. Those skilled in the art would be inspired by this disclosure to also vary the above parameters within a range of +/−20% of the specific values disclosed herein and still obtain the structure 300.

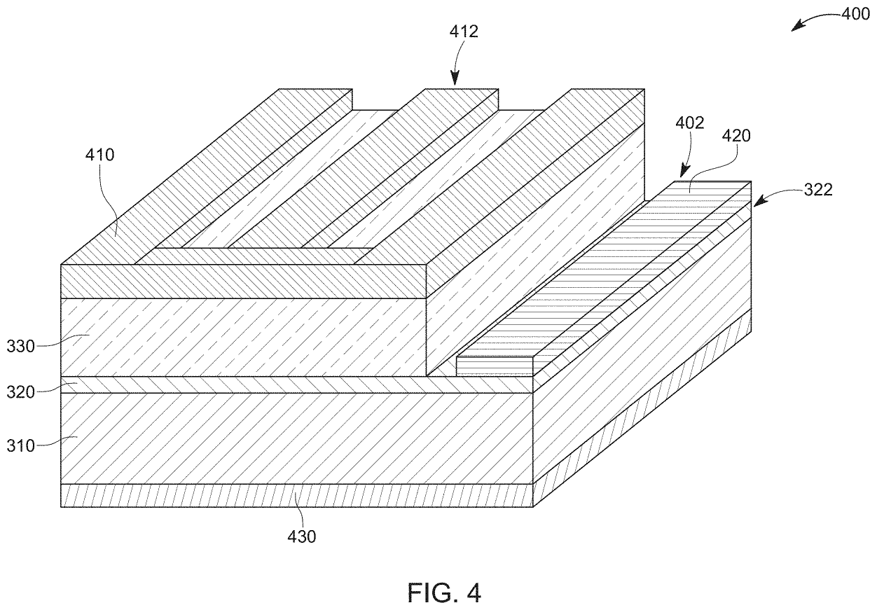

The optoelectronic structure 300 can be patterned to obtain a DUV photodetector 400 as illustrated in FIG. 4. An optional mesa region 402 exposing a portion 322 of the conductive TiN film 320 was defined using a shadow mask during the β-Ga₂O₃ film deposition by PLD. A top electrode 410 and another electrode 420 were patterned on the β-Ga₂O₃ film 330 and the TiN film 320, respectively, in the same step through a lift-off process using a 1.6 μm thick photoresist exposed using an optical direct-write lithography system. The top electrode 410 has in this embodiment five interconnected gold (Au)/Ti (150 nm/50 nm in thickness) parallel fingers 412 with 50 μm spacing, and it acts as a top contact electrode to the β-Ga₂O₃ film. The Au/Ti thin films 420 were deposited directly on the exposed TiN film 320, in the region 322, to obtain a vertically oriented β-Ga₂O₃/TiN photodetector 400. Alternatively or instead, the mesa region 402 can be formed through an area-selective etch down of the semiconductor film 330 and/or the top electrode 410 (which includes interconnected Au/Ti parallel fingers 412) to the portion 322 of the conductive TiN film 320 or the substrate 310. Moreover, the top electrode 410 and interconnected Au/Ti parallel fingers 412 can be formed through an area-selective etch down of blanket-deposited Au/Ti layers to the semiconductor film 330. Note that the top electrode can have any shape, including circular/ring, and the finger top electrode shown in FIG. 4 is just an example. A bottom electrode 430 can be implemented to realize a vertically oriented photodetector, and can be replaced by the metal electrode 420 deposited directly on the refractory transitional metal-ceramic film 320 through the mesa region 402. Thus, the device 400 can be used with or without the bottom electrode 430. When used without the bottom electrode 430, the device 400 can be operated by applying a reverse-bias between the metal films 410 and 420, which is the standard operating configuration and the photodetector measurements shown later are based on this configuration. Alternatively, when the device 400 is used with the bottom electrode 430, the device can be operated by applying a reverse-bias between the metal films 410 and 430, an operating configuration in which the refractory metal is used as a growth template but not as an efficient electrode.

Both device designs are expected to work similarly, but the mesa design allows for the photogenerated electron-hole pairs created by the UV light to be efficiently separated and transported to the metal contacts through the thick beta-β-Ga₂O₃ layer. When the bias is reversed (i.e., a negative voltage is applied at the Au/Ti/refractory-metal ceramic film side relative to that at the Au/Ti/semiconductor film side and electron flow is from the refractory-metal ceramic film to the semiconductor film, the device across the bottom/mesa electrodes becomes a vertically oriented device configuration. With the bias still reversed, the device across two separated Au/Ti contact points atop the semiconductor film becomes a horizontally/laterally oriented device configuration. A vertical photodetector configuration achieves a more efficient carrier separation. When a horizontal/lateral configuration is adopted, the TiN layer is not electrically utilized.

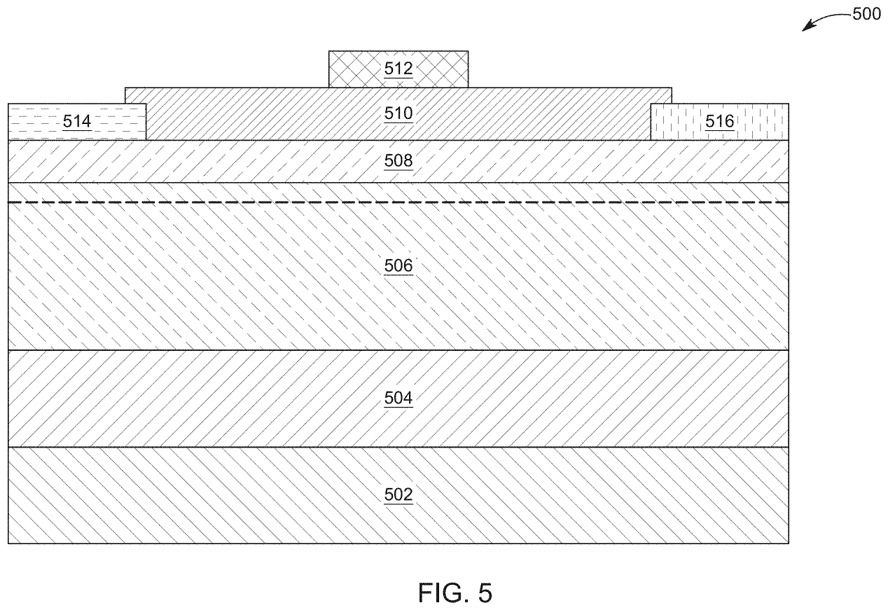

Many other semiconductor-based devices may be manufactured based on the method discussed above with regard to FIG. 2. A couple of such semiconductor devices are now discussed. FIG. 5 shows a HEMT power device 500 that is made based on the novel method. The HEMT power device 500 includes a Si substrate 502, a refractory transitional-metal-ceramic film 504 having a thickness less than 300 nm, a single-crystalline layer 506 of Ga₂O₃, a single-crystalline cap layer 508 of (AlₓGa₁₋ₓ)₂O₃ or boron (B)-doped or -alloyed Ga₂O₃ (BₓGa₁₋ₓ)₂O₃, a gate dielectric 510, a gate 512, a source 514, and a drain 516. Any cap layer 508 with a higher bandgap such as (AlₓGa₁₋ₓ)₂O₃ and (BₓGa₁₋ₓ)₂O₃ can be incorporated. To avoid relaxation faults, the cap layer 508 has a thickness of at most 20-25 nm. The film 504 may include any of the materials discussed above with regard to film 320.

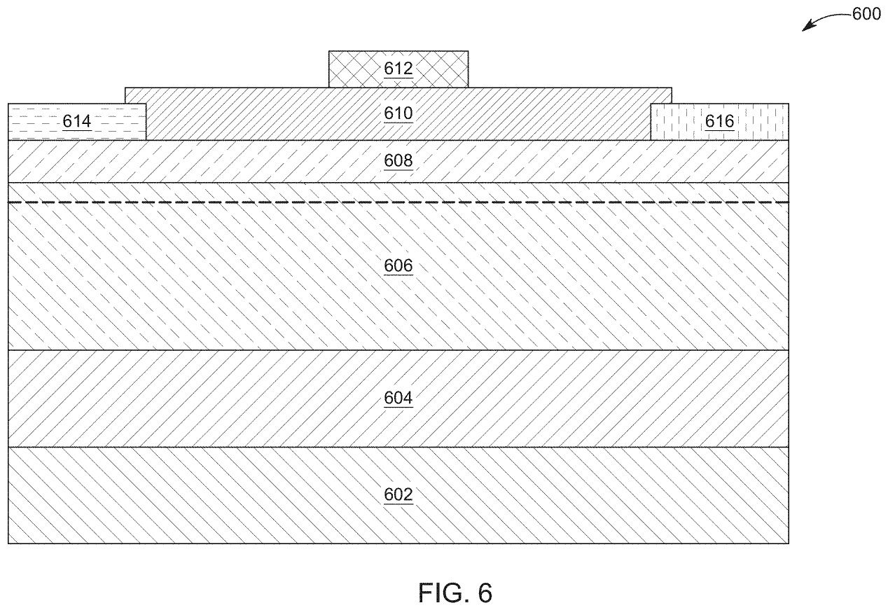

FIG. 6 shows another HEMT power device that is based on the novel method. The HEMT power device 600 includes a Si substrate 602 on which a refractory transitional-metal-ceramic film 604 is formed to have a thickness not more than 300 nm. The film 604 may include any of the materials discussed above with regard to film 320. A semiconductor layer 606 is then formed over the film refractory transitional-metal-ceramic film 604. In this embodiment, the semiconductor layer 606 is made of a single-crystalline indium gallium nitride (InₓGaN₁₋ₓ) material. A cap layer 608 is formed over the semiconductor layer 606. The cap layer 608 may include any material with higher bandgap, such as AlₓGa₁₋ₓN, boron aluminum nitride (BₓAl₁₋ₓN), and indium aluminum nitride (InₓAl₁₋ₓN). To avoid relaxation faults, the cap layer has a thickness of mostly 20-25 nm. A dielectric layer 610 is formed over the cap layer 608, and a gate 612 is formed over the dielectric layer. A source 614 and a drain 616 are formed over the cap layer 608, as shown in FIG. 6.

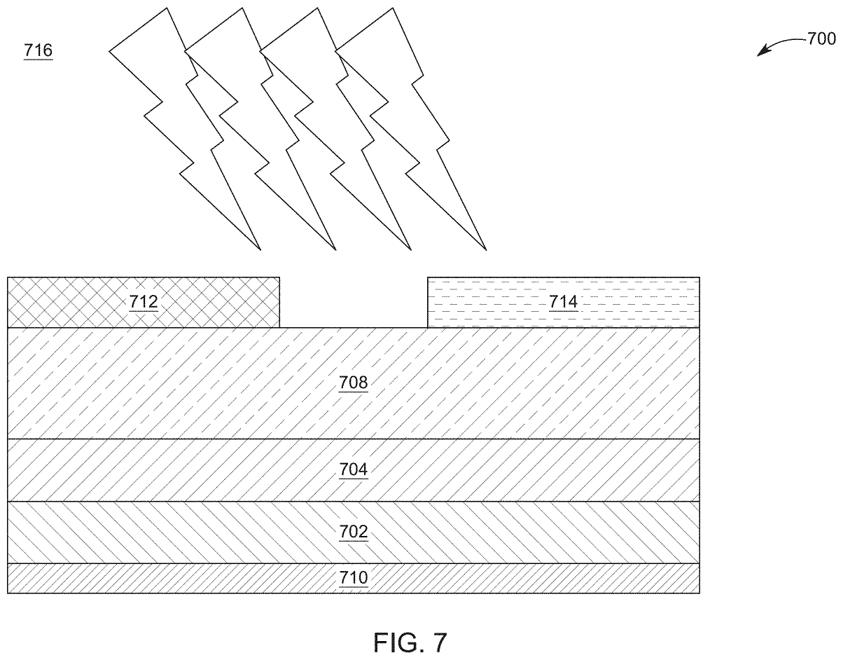

A UV detector 700 using the novel technology discussed herein is illustrated in FIG. 7. The detector 700 includes a substrate 702, for example, Si, over which a refractory transitional-metal ceramic film 704 is formed with the method discussed with regard to FIG. 2. A single-crystalline semiconductor layer 708 is formed over the refractory transitional-metal ceramic film 704. The semiconductor layer 708 may include a Ga₂O₃ alloy. Alternatively or instead, the layer 708 may be a thick light absorption layer or may include multiple quantum wells for absorbing light and transforming it into electrical energy. An optional bottom electrode 710 is formed on the substrate 702 and top electrodes 712 and 714 are formed apart from each other on the top layer 708, so that light 716 can enter the top layer 708. If the two top electrodes 712 and 714 are used, a laterally oriented photodetector 700 is obtained. If the bottom electrode 710 is used is used with one of the top electrodes 712 or 714, a vertically oriented photodetector is achieved. In one application, the bottom electrode 710 may be directly deposited on the refractory transitional-metal-ceramic film 704, through a mesa region, as illustrated in FIG. 4.

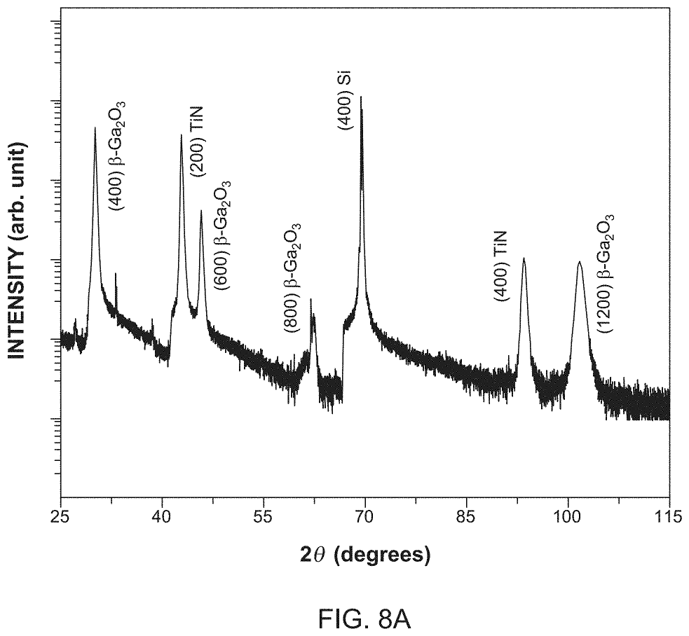

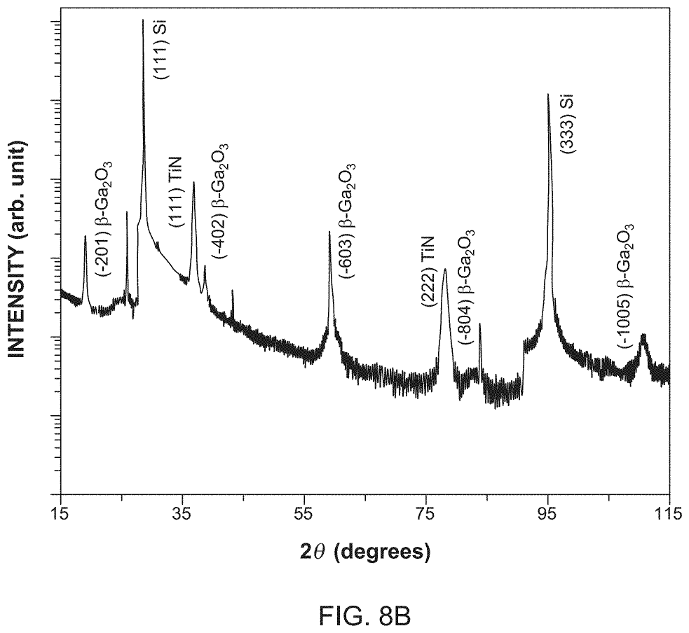

The optoelectronic structure 300, which was implemented in each of the devices 400 to 700 discussed above, has been characterized with various methods for ascertaining its properties. In one embodiment, a e-scan out-of-plane XRD pattern was acquired from the β-Ga₂O₃/TiN/(100)-cut Si stack 300, as shown in FIG. 8A, and a β-scan out-of-plane XRD pattern was acquired from a β-Ga₂O₃/TiN/(111)-cut Si stack, as shown in FIG. 8B, whereby parallel diffracting planes are detected irrespective of their rotations. The pattern in FIG. 8A indicate how the crystal axes are aligned with respect to each other in terms of normal vectors and a family of lattice planes, and one can confirm the following c-axis crystallographic plane relationship between the grown films 320 and 330 and the Si substrate 310,

(400)p-Ga₂O₃∥(200)TiN∥(400)Si,

where the symbol “∥” implies parallel planes. In other words, the out-of-plane XRD measurements of FIG. 8A provide the orientation relationship along the growth axis, i.e., the c-axis. The measured results closely fit the simulated out of plane XRD intensities. For the (111)-cut Si structure illustrated in FIG. 8B, the following crystallographic relationship can be confirmed,

(−201)β-Ga2O3∥(111)TiN∥(111)Si.

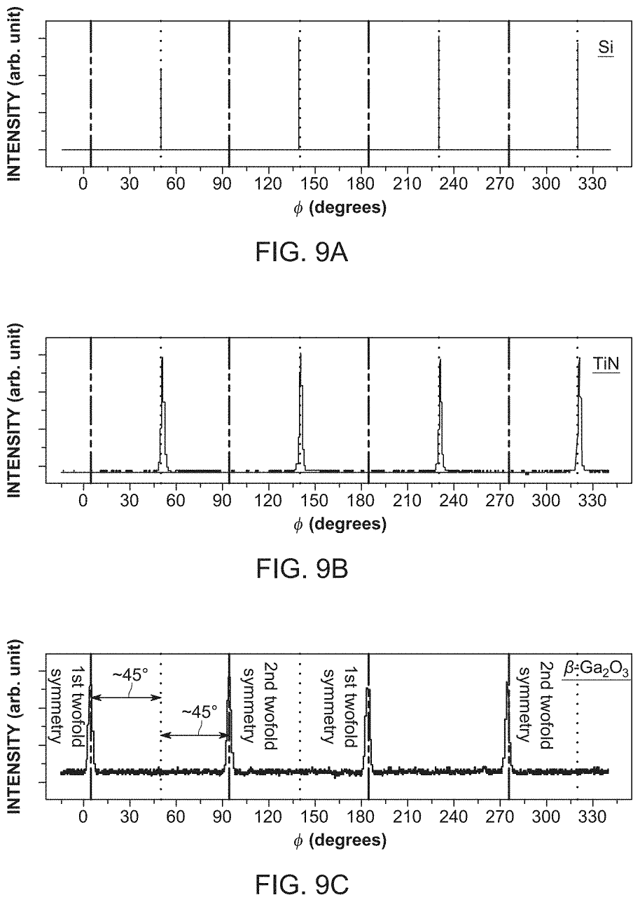

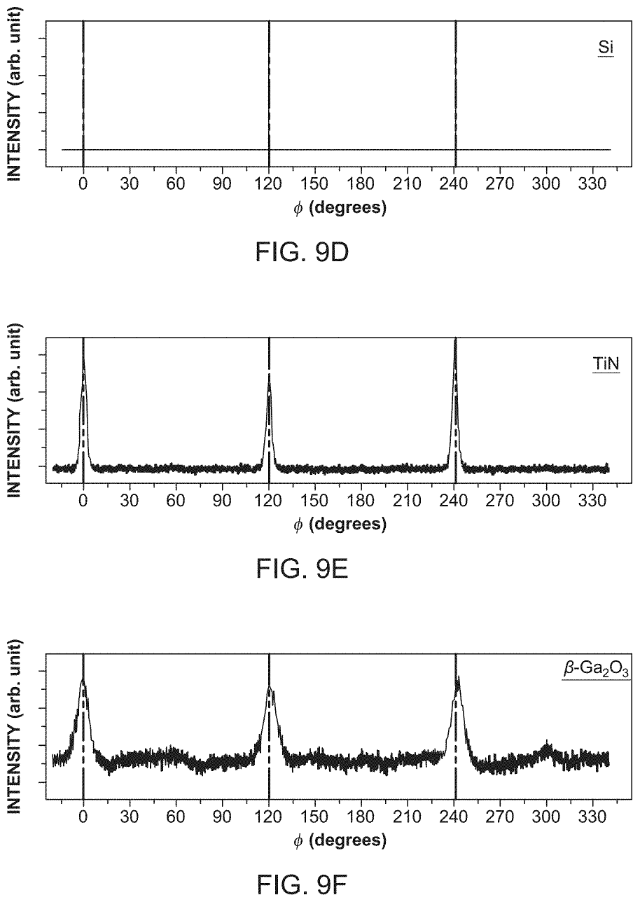

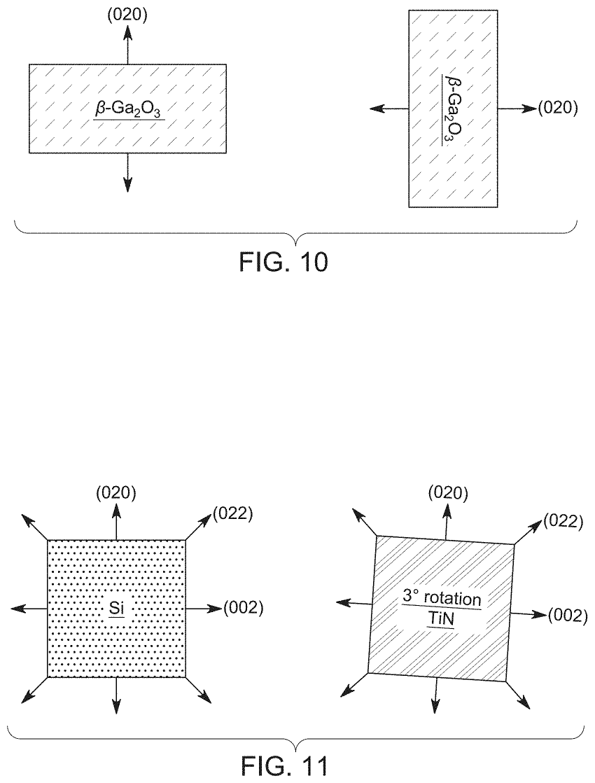

Next, the optoelectronic structure 300 was investigated with another XRD method, and FIGS. 9A to 9C present the φ-scan skewed asymmetric XRD measurements for the (100)-cut Si substrate 310, TiN thin film 320, and the β-Ga₂O₃ film 330, respectively, while FIGS. 9D to 9F present the same measurements for the (111)-cut Si substrate, TiN thin film, and the β-Ga₂O₃ film 330, respectively. Parallel diffracting planes were detected with respect to their rotations in FIGS. 9A to 9C. These measurements reveal how the crystal axes are aligned azimuthally with respect to each other. The results in FIGS. 9D to 9E show that the (−401) β-Ga₂O₃ is aligned with (200) TiN and (400) Si and that the following crystallographic relationship can be confirmed: (010) β-Ga2O3∥(1-10) TiN∥(1-10) Si. Four (420) β-Ga₂O₃ asymmetric Bragg reflections that are separated by 45° were observed in FIGS. 9A to 9C, indicating that the planes are orthogonal to each other. However, when these XRD results are combined with observations from transmission electron microscopy (TEM) analysis and crystal model simulations, it is conjectured that there are two β-Ga₂O₃ unit cell configurations that provide double twofold symmetry: two (420) β-Ga₂O₃ Bragg reflections that originate from the configuration rotated about 45° to the right, and the other two (420) β-Ga₂O₃ Bragg reflections originating from the configuration rotated about 45° to the left, as illustrated in FIG. 10. Otherwise, if there were no multiple-unit cell configurations present in the grown lattice, only two XRD Bragg reflections should be observed. Also, once one zooms in on any of the plane Bragg reflection pairs (the first Bragg reflection pair consists of the first and third Bragg reflection peaks), it is noted that the (420) β-Ga₂O₃ plane Bragg reflection split because the β-Ga₂O₃ lattice's two configurations exhibit further rotation of 0.85° to the left/right (twin-domain structure). The (220) TiN is almost parallel to the (220) Si, with only a 3° rotation, as illustrated in FIG. 11.

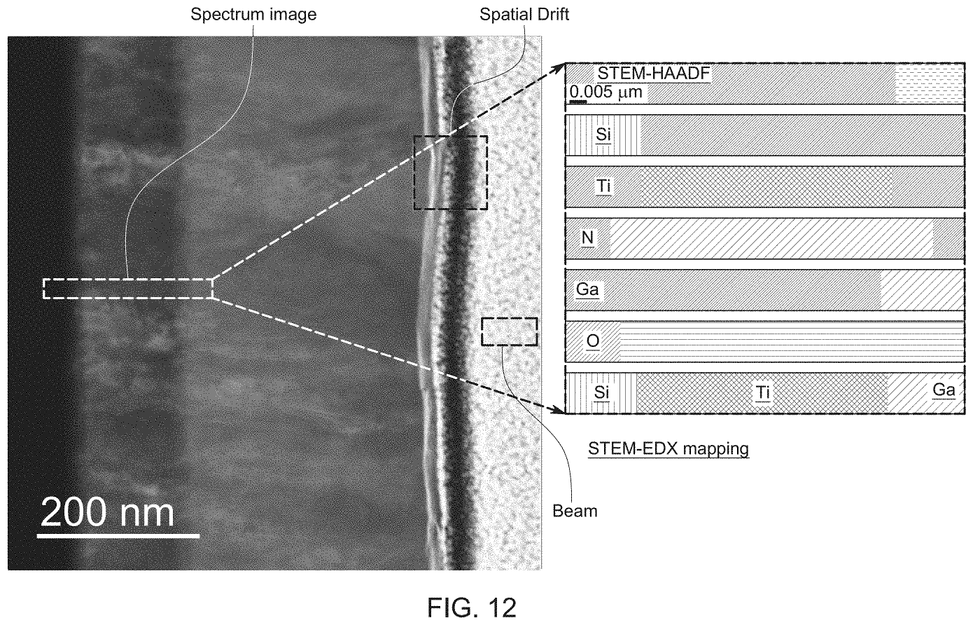

FIG. 12 presents the elemental mapping of the structure 300 (for the (100)-cut Si) obtained using energy-dispersive X-ray (EDX) analysis combined with scanning transmission electron microscopy (STEM) and high-angle annular dark-field (HAADF) micrography. FIG. 12 presents the energy spectrum obtained during this analysis. These techniques were used to confirm the chemical composition of each deposited film. It is observed the sharp layer transitions and high quality of interfaces in the heterostructure stack of β-Ga₂O₃/TiN through the HRTEM micrography. The part of the image on the left-hand side displays a cross-sectional STEM micrograph of the sample, whereas the part to the right of the image shows an HAADF micrograph with EDX spectra that confirm each layer's composition and thickness and the low thermally induced interdiffusion characteristics during layer growth.

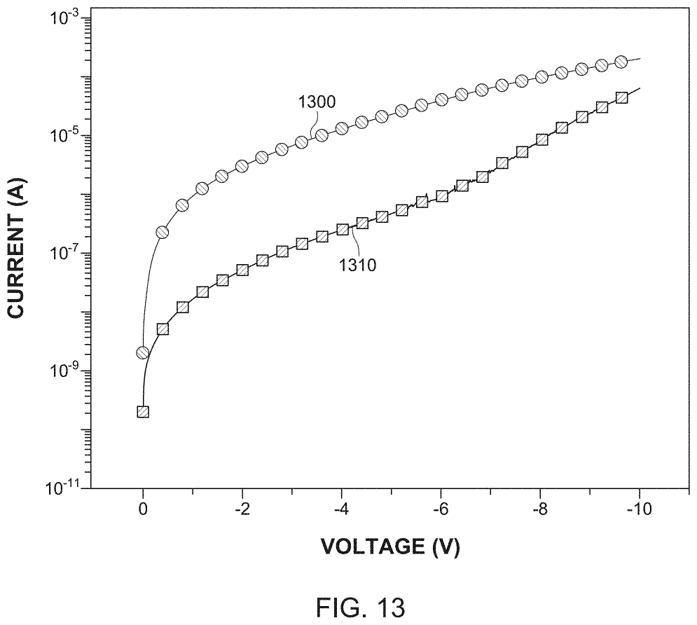

FIG. 13 shows the current-voltage measurements for the DUV photodetector 700 employing the (100)-cut Si that includes the structure 300 and show that the photogenerated current 1300 is up to 100 times stronger than the dark current 1310, for a biased voltage between −2 and −6 V.

The characteristics discussed above with regard to the structure 300 indicate that high-efficiency and low-cost Si-integrated optoelectronics can be obtained based on the method illustrated in FIG. 2. Such optoelectronics are reliable and support high-performance Si-integrated power electronics with integral heat sinks. In one application, the refractory transitional-metal ceramic film constitutes a high-quality current spreading layer because these films are very good electrical conductors. The refractory transitional-metal ceramic films can also be used as anti-diffusion layers, enabling higher number of operating cycles of a device as well as increased operating temperatures.

The disclosed embodiments provide a method for growing semiconductor materials on common Si substrates with a thin refractory transitional-metal ceramic film. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] A. Zaher, S. Li, O. Yassine, N. Khashab, N. Pirmoradi, L. Lin, J. Kosel: “Osmotically driven drug delivery through remote-controlled magnetic nanocomposite membranes”. Biomicrofluidics, vol. 9, no. 5, p. 054113, 2015.
[2] Choi, C. H., Hultman, L., Chiou, W. A., & Barnett, S. A. (1991). Growth of epitaxial TiN thin films on Si (100) by reactive magnetron sputtering. Journal of Vacuum Science & Technology B: Microelectronics and Nanometer Structures Processing, Measurement, and Phenomena, 9(2), 221-227.
[3] Sheu, W. H., & Wu, S. T. (1998). Epitaxial growth of TiC (002) on Si (001) by reactive magnetron sputtering at low temperatures. Japanese Journal of Applied Physics, 37(11R), 6094.
[4] Barnett, S. A., Hultman, L., Sundgren, J. E., Ronin, F., & Rohde, S. (1988). Epitaxial growth of ZrN on Si (100). Applied Physics Letters, 53(5), 400-402.
[5] Wang, H., Tiwari, A., Kvit, A., Zhang, X., & Narayan, J. (2002). Epitaxial growth of TaN thin films on Si (100) and Si (111) using a TiN buffer layer. Applied Physics Letters, 80(13), 2323-2325.
[6] Naiki, T., Ninomiya, M., & Ihara, M. (1972). Epitaxial growth of tantalum carbide. Japanese Journal of Applied Physics, 11(8), 1106.
[7] Liu, X., Lu, H., He, M., Jin, K., Yang, G., Ni, H., & Zhao, K. (2014). Epitaxial growth of vanadium nitride thin films by laser molecule beam epitaxy. Materials Letters, 123, 38-40.
[8] Moram, M. A., Novikov, S. V., Kent, A. J., Nörenberg, C., Foxon, C. T., & Humphreys, C. J. (2008). Growth of epitaxial thin films of scandium nitride on 100-oriented silicon. Journal of Crystal Growth, 310(11), 2746-2750.
[9] Inumaru, K., Okamoto, H., & Yamanaka, S. (2002). Preparation of superconducting epitaxial thin films of transition metal nitrides on silicon wafers by molecular beam epitaxy. Journal of Crystal Growth, 237, 2050-2054.
[10] Xu, X., Armitage, R., Shinkai, S., Sasaki, K., Kisielowski, C., & Weber, E. R. (2005). Epitaxial condition and polarity in GaN grown on a HfN-buffered Si (111) wafer. Applied Physics Letters, 86(18), 182104.
[11] Armitage, R., Yang, Q., Feick, H., Gebauer, J., Weber, E. R., Shinkai, S., & Sasaki, K. (2002). Lattice-matched HfN buffer layers for epitaxy of GaN on Si. Applied Physics Letters, 81(8), 1450-1452.
[12] Wang, J., Feng, M., Zhou, R., Sun, Q., Liu, J., Huang, Y., . . . & Yang, H. (2019). GaN-based ultraviolet microdisk laser diode grown on Si. Photonics Research, 7(6), B32-B35.

1. A method for growing a semiconductor material over a Si-based substrate, the method comprising:
providing the Si-based substrate;
growing a monocrystalline refractory-metal ceramic film directly over the Si-based substrate; and
depositing a semiconductor film directly over the monocrystalline refractory-metal ceramic film,
wherein the monocrystalline refractory-metal ceramic film has a thickness less than 300 nm.

2. The method of claim 1, wherein the monocrystalline refractory-metal ceramic film includes TiN.

3. The method of claim 2, wherein the semiconductor film includes Ga₂O₃.

4. The method of claim 1, further comprising:
removing a native oxide layer of the Si-based substrate before growing the monocrystalline refractory-metal ceramic film.

5. The method of claim 1, wherein the step of growing comprises:
applying radio-frequency magnetron sputtering with Ti target in a reactive mixture of Ar and N₂ gases.

6. The method of claim 5, wherein the step of depositing comprises:
depositing Ga₂O₃ as the semiconductor film, using pulsed laser deposition, wherein a thickness of the deposited Ga₂O₃ film is less than 400 nm.

7. The method of claim 1, further comprising:
exposing a portion of the monocrystalline refractory-metal ceramic film;
forming a first electrode on the monocrystalline refractory-metal ceramic film; and
forming a second electrode on the Si-based substrate.

8. A photodetector comprising:
a Si-based substrate;
a monocrystalline refractory-metal ceramic film located directly over the Si-based substrate;
a semiconductor film located directly over the monocrystalline refractory-metal ceramic film; and
first and second electrodes,
wherein the monocrystalline refractory-metal ceramic film has a thickness less than 300 nm.

9. The photodetector of claim 8, wherein the monocrystalline refractory-metal ceramic film includes TiN.

10. The photodetector of claim 9, wherein the semiconductor film includes a single-crystalline Ga₂O₃ film.

11. The photodetector of claim 8, wherein there is no native oxide layer between the Si-based substrate and the monocrystalline refractory-metal ceramic film.

12. The photodetector of claim 10, wherein a thickness of the Ga₂O₃ film is less than 400 nm.

13. The photodetector of claim 8, wherein both the first and second electrodes are formed on the semiconductor film.

14. The photodetector of claim 8, wherein the first electrode is formed on the Si-based substrate and the second electrode is formed on the semiconductor film.

15. A transistor comprising:
a Si-based substrate;
a monocrystalline refractory-metal ceramic film located directly over the Si-based substrate;
a semiconductor film located directly over the monocrystalline refractory-metal ceramic film;
a cap layer formed over the semiconductor film;
a dielectric layer formed over the cap layer;
a gate formed over the dielectric layer; and
source and drain regions formed directly on the cap layer,
wherein the monocrystalline refractory-metal ceramic film has a thickness less than 300 nm.

16. The transistor of claim 15, wherein the monocrystalline refractory-metal ceramic film includes TiN.

17. The transistor of claim 16, wherein the semiconductor film includes a single-crystalline InGaN.

18. The transistor of claim 17, wherein the cap layer includes AlₓGa₁₋ₓN or B doped AlN.

19. The transistor of claim 15, wherein there is no native oxide layer between the Si-based substrate and the monocrystalline refractory-metal ceramic film.

20. The transistor of claim 15, wherein a thickness of the semiconductor film is less than 400 nm.
